(19) United States
(12) Patent Application Publication
(10) Pub. No.: US 2025/0133855 A1
(43) Pub. Date: Apr. 24, 2025

(54) IMAGING DEVICE

(71) Applicant: SONY SEMICONDUCTOR SOLUTIONS CORPORATION, KANAGAWA (JP)

(72) Inventor: YOSHINORI KODAMA, KANAGAWA (JP)

(21) Appl. No.: 18/687,904

(22) PCT Filed: Mar. 11, 2022
(86) PCT No.: PCT/JP2022/011045

§ 371 Date: Feb. 29, 2024

(30) Foreign Application Priority Data
Sep. 22, 2021 (JP) 2021-153998

(51) Int. Cl. H10F 39/00; H10F 39/18

(52) U.S. Cl. CPC H10F 39/807; H10F 39/014; H10F 39/182

(57) ABSTRACT

There is provided an imaging device that can suppress deterioration in characteristics. An imaging device includes: a support substrate that includes a first compound semiconductor; a photoelectric conversion layer that is provided on a first surface side of the support substrate and includes a second compound semiconductor having a composition different from a composition of the first compound semiconductor; a first protective layer that is provided in a trench penetrating the support substrate and the photoelectric conversion layer and is provided on a first side surface of the photoelectric conversion layer; and a second protective layer that is provided in the trench and is provided on a second side surface of the support substrate. The first protective layer and the second protective layer have different compositions. A first interface state generated between the first side surface and the first protective layer is smaller than an interface state generated between the first side surface and the second protective layer in a case where the second protective layer is in contact with the first side surface. A second interface state generated between the second side surface and the second protective layer is smaller than an interface state generated between the second side surface and the first protective layer in a case where the first protective layer is in contact with the second side surface.

### DESCRIPTION

### Technical Field

The present disclosure relates to an imaging device.

### Background Art

A compound semiconductor such as InGaAs having high quantum conversion efficiency in the infrared region is expected as a photoelectric conversion film for a next-generation image sensor. In a compound sensor that has already been put into practical use, since the photoelectric conversion portion and the circuit portion are bump-connected (see, for example, Patent Document 1), the pixel pitch size is minimized to about 10 μm, but from now on, it is considered that pixel miniaturization proceeds for the purpose of further improving the characteristics of the compound region.

At that time, a structure for separating pixels has already been proposed (see, for example, Patent Document 2). The light receiving element disclosed in Patent Document 2 includes a photoelectric conversion layer containing a group IIIV semiconductor, a plurality of first conductivity-type regions to which signal charges generated in the photoelectric conversion layer move, and a second conductivity-type region penetrating the photoelectric conversion layer and provided between adjacent first conductivity-type regions.

### CITATION LIST

### Patent Document

### Patent Document 1: Japanese Unexamined Patent Application Publication No. 2014-521216

### Patent Document 2: Japanese Patent Application Laid-Open No. 2018-37611

### SUMMARY OF THE INVENTION

### Problems to be Solved by the Invention

In the light receiving element disclosed in Patent Document 1, the second conductivity-type region covers and protects the side surface of the photoelectric conversion layer and the side surface of the first conductivity-type region. In a case where the photoelectric conversion layer and the first conductivity-type region include compound semiconductors having compositions different from each other, the interface between the photoelectric conversion layer and the second conductivity-type region and the interface between the first conductivity-type region and the second conductivity-type region are interfaces in which bonding states of atoms are different from each other.

Here, if the material of the second conductivity-type region is selected such that one of the interface between the photoelectric conversion layer and the second conductivity-type region and the interface between the first conductivity-type region and the second conductivity-type region becomes an optimum interface, the other interface is not optimized, and the interface state of the other interface may increase. If the interface state increases, dark current increases, and there is a possibility that the characteristics of the light receiving element is deteriorated.

The present disclosure has been made in view of such circumstances, and an object thereof is to provide an imaging device that can suppress deterioration in characteristics.

### Solutions to Problems

An imaging device according to an aspect of the present disclosure includes: a support substrate that includes a first compound semiconductor; a photoelectric conversion layer that is provided on a first surface side of the support substrate and includes a second compound semiconductor having a composition different from a composition of the first compound semiconductor; a first protective layer that is provided in a trench penetrating the support substrate and the photoelectric conversion layer and is provided on a first side surface of the photoelectric conversion layer; and a second protective layer that is provided in the trench and is provided on a second side surface of the support substrate. The first protective layer and the second protective layer have different compositions. A first interface state generated between the first side surface and the first protective layer is smaller than an interface state generated between the first side surface and the second protective layer in a case where the second protective layer is in contact with the first side surface. A second interface state generated between the second side surface and the second protective layer is smaller than an interface state generated between the second side surface and the first protective layer in a case where the first protective layer is in contact with the second side surface.

According to this, it is possible to select an optimum protective layer for each of the first side surface of the photoelectric conversion layer and the second side surface of the support substrate, and it is possible to reduce both the first interface state of the first side surface and the second interface state of the second side surface. Therefore, for example, since dark current can be reduced, deterioration in the characteristics of the light receiving element can be suppressed.

### BRIEF DESCRIPTION OF DRAWINGS

FIG. 1 is a cross-sectional view illustrating a configuration example of a light receiving element according to a first embodiment of the present disclosure.

FIG. 2 is a cross-sectional view illustrating a configuration example of a pixel isolation portion of the light receiving element according to the first embodiment of the present disclosure.

FIG. 3 is a plan view illustrating a configuration example of one pixel of the light receiving element according to the first embodiment of the present disclosure.

FIG. 4A is a plan view illustrating an example of the shape of the pixel isolation portion in plan view according to the first embodiment of the present disclosure.

FIG. 4B is a plan view illustrating an example of the shape of the pixel isolation portion in plan view according to the first embodiment of the present disclosure.

FIG. 4C is a plan view illustrating an example of the shape of the pixel isolation portion in plan view according to the first embodiment of the present disclosure.

FIG. 5A is a cross-sectional view illustrating a method for manufacturing the light receiving element according to the first embodiment of the present disclosure in order of process.

FIG. 5B is a cross-sectional view illustrating the method for manufacturing the light receiving element according to the first embodiment of the present disclosure in order of process.

FIG. 5C is a cross-sectional view illustrating the method for manufacturing the light receiving element according to the first embodiment of the present disclosure in order of process.

FIG. 5D is a cross-sectional view illustrating the method for manufacturing the light receiving element according to the first embodiment of the present disclosure in order of process.

FIG. 5E is a cross-sectional view illustrating the method for manufacturing the light receiving element according to the first embodiment of the present disclosure in order of process.

FIG. 5F is a cross-sectional view illustrating the method for manufacturing the light receiving element according to the first embodiment of the present disclosure in order of process.

FIG. 6 is a cross-sectional view illustrating a first modification of the pixel isolation portion of the light receiving element according to the first embodiment of the present disclosure.

FIG. 7 is a cross-sectional view illustrating a second modification of the pixel isolation portion of the light receiving element according to the first embodiment of the present disclosure.

FIG. 8 is a cross-sectional view illustrating a third modification of the pixel isolation portion of the light receiving element according to the first embodiment of the present disclosure.

FIG. 9 is a cross-sectional view illustrating a fourth modification of the pixel isolation portion of the light receiving element according to the first embodiment of the present disclosure.

FIG. 10 is a graph illustrating results of simulating interface adhesion.

FIG. 11 is a cross-sectional view illustrating a configuration example of a pixel isolation portion of a light receiving element according to a second embodiment of the present disclosure.

FIG. 12A is a cross-sectional view illustrating a method for manufacturing the light receiving element according to the second embodiment of the present disclosure in order of process.

FIG. 12B is a cross-sectional view illustrating the method for manufacturing the light receiving element according to the second embodiment of the present disclosure in order of process.

FIG. 12C is a cross-sectional view illustrating the method for manufacturing the light receiving element according to the second embodiment of the present disclosure in order of process.

FIG. 12D is a cross-sectional view illustrating the method for manufacturing the light receiving element according to the second embodiment of the present disclosure in order of process.

FIG. 13 is a cross-sectional view illustrating a modification of the pixel isolation portion of the light receiving element according to the second embodiment of the present disclosure.

FIG. 14 is a cross-sectional view illustrating a configuration example of a pixel isolation portion of a light receiving element according to a third embodiment of the present disclosure.

FIG. 15A is a cross-sectional view illustrating a method for manufacturing the light receiving element according to the third embodiment of the present disclosure in order of process.

FIG. 15B is a cross-sectional view illustrating the method for manufacturing the light receiving element according to the third embodiment of the present disclosure in order of process.

FIG. 15C is a cross-sectional view illustrating the method for manufacturing the light receiving element according to the third embodiment of the present disclosure in order of process.

FIG. 16 is a cross-sectional view illustrating a modification of the pixel isolation portion of the light receiving element according to the third embodiment of the present disclosure.

FIG. 17 is a cross-sectional view illustrating a configuration example of a pixel isolation portion of a light receiving element according to a fourth embodiment of the present disclosure.

FIG. 18 is a cross-sectional view illustrating a modification of the pixel isolation portion of the light receiving element according to the fourth embodiment of the present disclosure.

FIG. 19 is a cross-sectional view illustrating a configuration example of a pixel isolation portion of a light receiving element according to a fifth embodiment of the present disclosure.

FIG. 20 is a cross-sectional view illustrating a modification of the pixel isolation portion of the light receiving element according to the fifth embodiment of the present disclosure.

FIG. 21 is a cross-sectional view illustrating a configuration example of a pixel isolation portion of a light receiving element according to a sixth embodiment of the present disclosure.

FIG. 22 is a cross-sectional view illustrating a modification of the pixel isolation portion of the light receiving element according to the sixth embodiment of the present disclosure.

FIG. 23 is a cross-sectional view illustrating a configuration example of a pixel isolation portion of a light receiving element according to a seventh embodiment of the present disclosure.

FIG. 24 is a cross-sectional view illustrating a modification of the pixel isolation portion of the light receiving element according to the seventh embodiment of the present disclosure.

FIG. 25 is a cross-sectional view illustrating a configuration example of a pixel isolation portion of a light receiving element according to an eighth embodiment of the present disclosure.

FIG. 26 is a cross-sectional view illustrating a modification of the pixel isolation portion of the light receiving element according to the eighth embodiment of the present disclosure.

FIG. 27 is a diagram illustrating a functional configuration example of an imaging device according to an embodiment of the present disclosure.

### MODE FOR CARRYING OUT THE INVENTION

Hereinafter, embodiments of the present disclosure will be described with reference to the drawings. In the description of the drawings referred to in the following description, the same or similar parts are denoted by the same or similar reference signs. However, it should be noted that the drawings are schematic, and a relationship between a thickness and a planar dimension, a ratio of the thicknesses between respective layers, and the like are different from the actual ones. Therefore, specific thicknesses and dimensions should be determined in consideration of the following description. Also, it goes without saying that dimensional relationships and ratios are partly different between the drawings.

Furthermore, definitions of directions such as up and down in the following description are merely definitions for convenience of description, and do not limit the technical idea of the present disclosure. For example, it goes without saying that if a target is observed while being rotated by 90°, the upward and downward directions are converted into rightward and leftward, and if the target is observed while being rotated by 180°, the upward and downward are inverted.

### First Embodiment

### (Configuration Example of Light Receiving Element)

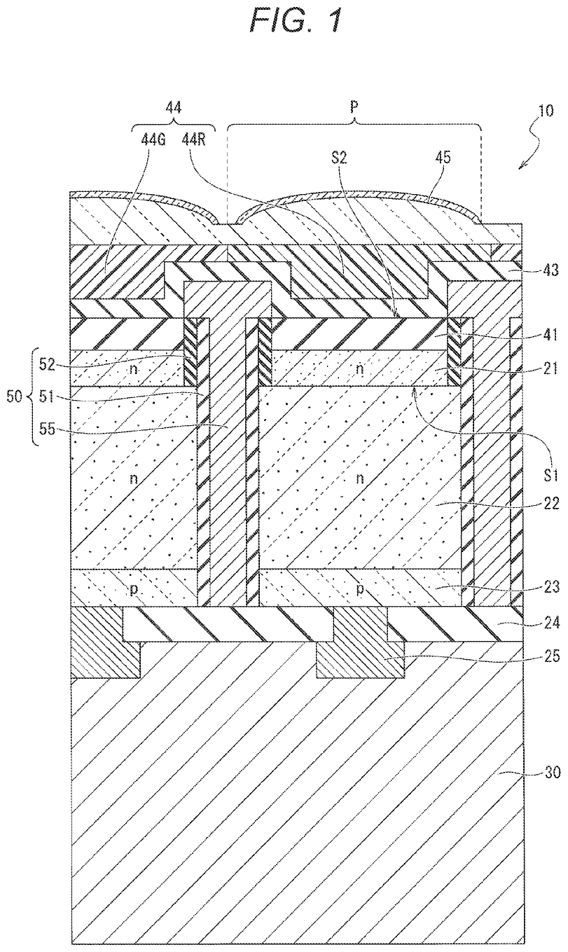

FIG. 1 is a cross-sectional view illustrating a configuration example of a compound semiconductor light receiving element (hereinafter, also simply referred to as a “light receiving element”) 10 according to a first embodiment of the present disclosure. The light receiving element 10 is applied to, for example, an infrared sensor or the like, and includes a plurality of light receiving unit regions (referred to as pixels P) arranged two-dimensionally.

The light receiving element 10 includes a semiconductor substrate 21 of a first conductivity type (for example, n-type), and a photoelectric conversion layer 22 including a semiconductor layer of the first conductivity-type (for example, n-type), a semiconductor layer 23 of a second conductivity-type (for example, p-type), a first insulating film 24, and a multilayer wiring substrate 30 are provided in this order on a first surface S1 of the n-type semiconductor substrate 21. The photoelectric conversion layer 22 and the p-type semiconductor layer 23 are provided for each pixel P. The light receiving element 10 includes an electrode 25 penetrating the first insulating film 24, and the semiconductor layer 23 and a readout integrated circuit (ROIC) of the multilayer wiring substrate 30 are electrically connected by the electrode 25. On a second surface S2 of the semiconductor substrate 21, a second insulating film 41, a light shielding layer 55, a third insulating film 43, a color filter 44, and an on-chip lens 45 are provided in this order.

The semiconductor substrate 21 includes, for example, an n-type compound semiconductor. As an example, the semiconductor substrate 21 is an n-type indium phosphide (InP) substrate. FIG. 1 illustrates a case where the photoelectric conversion layer 22 is provided in contact with the first surface S1 of the semiconductor substrate 21, but another layer may exist between the semiconductor substrate 21 and the photoelectric conversion layer 22. Examples of the material of the layer existing between the semiconductor substrate 21 and the photoelectric conversion layer 22 include semiconductor materials such as InAlAs, Ge, Si, GaAs, and InP, and it is preferable to select a material having lattice matching between the semiconductor substrate 21 and the photoelectric conversion layer 22.

The semiconductor substrate 21 is provided with a pixel isolation portion 50 between adjacent pixels P. The pixel isolation portion 50 includes a trench H provided in the semiconductor substrate 21, and a first protective layer 51, a second protective layer 52, and a light shielding layer 55 disposed in the trench H. The semiconductor substrate 21 and the photoelectric conversion layer 22 are divided for each pixel P by the trench H. The pixel isolation portion 50 can prevent movement of signal charges between the pixels P via the photoelectric conversion layer 22.

The photoelectric conversion layer 22 absorbs light having a predetermined wavelength (for example, light having a wavelength in the infrared region) to generate signal charges (electrons or holes), and includes a group III-V semiconductor. The photoelectric conversion layer 22 may be referred to as a light receiving layer.

Examples of the group III-V semiconductor used for the photoelectric conversion layer 22 include indium gallium arsenide (InGaAs). The composition of InGaAs is, for example, InxGa (1−x) As (x: 0<x≤1). In order to increase the sensitivity in the infrared region, x≥0.4 is preferable. An example of the composition of the photoelectric conversion layer 22 lattice-matched with the semiconductor substrate 21 including InP is In0.53Ga0.47As.

The photoelectric conversion layer 22 includes, for example, an n-type group III-V semiconductor, and contains a group IV element or a group VI element to be an n-type impurity. Examples of the group IV element include carbon (C), silicon (Si), germanium (Ge), and tin (Sn), and examples of the group VI element include sulfur (S), selenium (Se), and tellurium (Te). The concentration of the n-type impurity is, for example, 2×10¹⁷/cm³ or less. The photoelectric conversion layer 22 may include a p-type (first conductivity-type) group III-V semiconductor.

The semiconductor layer 23 is provided between the photoelectric conversion layer 22 and the first insulating film 24. The semiconductor layer 23 preferably includes a compound semiconductor having a band gap larger than that of the photoelectric conversion layer 22. For example, in a case where the photoelectric conversion layer 22 includes In0.53Ga0.47As (band gap 0.74 eV), the semiconductor layer 23 preferably includes InP (band gap 1.34 eV) or InAlAs (band gap about 1.56 eV).

The semiconductor layer 23 is provided for each pixel P such that the semiconductor layers 23 are separated from each other. The semiconductor layer 23 is a region to which signal charges generated in the photoelectric conversion layer 22 move, and is, for example, a region containing a p-type impurity (p-type impurity region). The semiconductor layer 23 contains, for example, a p-type impurity such as zinc (Zn).

The first insulating film 24 is provided between the semiconductor layer 23 and the multilayer wiring substrate 30, and includes, for example, an inorganic insulating material. Examples of the inorganic insulating material include silicon oxide (SiO₂), silicon nitride (SiN), aluminum oxide (Al₂O₃), and hafnium oxide (HfO₂). As an example, the first insulating film 24 is a SiO₂ film (hereinafter, a TEOS film) formed by a chemical vapor deposition (CVD) method using tetraethoxysilane (TEOS) as a material. A through hole is provided for each pixel P in the first insulating film 24, and the electrode 25 is provided in the through hole.

The electrode 25 penetrates the first insulating film 24, and for example, a part thereof is embedded in the multilayer wiring substrate 30. The electrode 25 is provided for each pixel P, and is electrically connected to the corresponding semiconductor layer 23 and the corresponding ROIC (ROIC 31 described later) of the multilayer wiring substrate 30. A voltage for reading signal charges generated in the photoelectric conversion layer 22 is supplied to the electrode 25. One electrode 25 may be provided for one pixel P, or a plurality of electrodes 25 may be provided for one pixel P. Some of the plurality of electrodes 25 provided for one pixel P may be dummy electrodes (electrodes that do not contribute to charge extraction).

The electrode 25 includes, for example, any one of titanium (Ti), tungsten (W), titanium nitride (TiN), platinum (Pt), gold (Au), germanium (Ge), palladium (Pd), zinc (Zn), nickel (Ni), or aluminum (Al), or an alloy containing at least one of them. The electrode 25 may be a single film of such a constituent material, or may be a laminated film obtained by combining two or more kinds of the materials.

In the multilayer wiring substrate 30, the ROIC for reading a signal from the pixel P is provided for each pixel P.

The second insulating film 41 is provided on the second surface S2 of the semiconductor substrate 21. The second insulating film 41 is provided on the entire second surface S2 of the semiconductor substrate 21 and has a trench between the adjacent pixels P. The pixel isolation portion 50 is embedded in the trench. The second insulating film 41 includes, for example, an inorganic insulating material. Examples of the inorganic insulating material include silicon oxide (SiO₂), silicon nitride (SiN), aluminum oxide (Al₂O₃), and hafnium oxide (HfO₂). As an example, the second insulating film 41 is a TEOS film.

The third insulating film 43 is provided on the entire second surface S2 of the semiconductor substrate 21 and covers the second insulating film 41 and the light shielding layer 55. The third insulating film 43 includes, for example, an inorganic insulating material. Examples of the inorganic insulating material include silicon nitride (SiN), aluminum oxide (Al₂O₃), silicon oxide (SiO₂), and hafnium oxide (HfO₂).

The color filter 44 is provided on the third insulating film 43 and includes, for example, a red filter (red filter 44R), a green filter (green filter 44G), a blue filter (not illustrated), and an IR filter (not illustrated). In the light receiving element 10, for example, any one of the filters is arranged for each pixel P such that the filters are arranged in a regular color array (for example, Bayer array). By providing such a color filter 44, the light receiving element 10 can obtain light reception data of wavelengths corresponding to the color array.

The on-chip lens 45 has a function of condensing light toward the photoelectric conversion layer 22, and includes, for example, an organic material, silicon oxide (SiO₂), or the like.

### (Configuration Example of Pixel Isolation Portion)

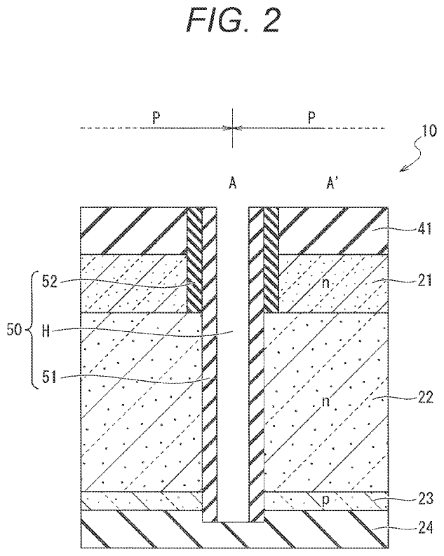

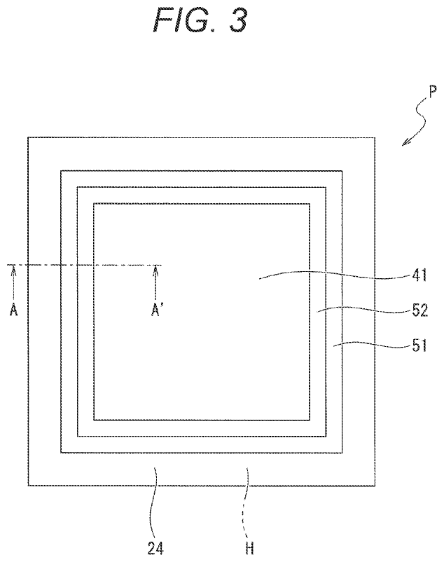

FIG. 2 is a cross-sectional view illustrating a configuration example of the pixel isolation portion 50 of the light receiving element 10 according to the first embodiment of the present disclosure. FIG. 3 is a plan view illustrating a configuration example of one pixel P of the light receiving element 10 according to the first embodiment of the present disclosure. A cross section taken along line A-A′ in FIG. 3 corresponds to a cross section of a portion on the right side of the trench H in FIG. 2. Note that, in FIGS. 2 and 3, illustration of the light shielding layer 55 (see FIG. 1) is omitted.

As illustrated in FIG. 2, the pixel isolation portion 50 has the trench H. The trench H penetrates the second insulating film 41, the semiconductor substrate 21, the n-type photoelectric conversion layer 22, and the semiconductor layer 23. As illustrated in FIG. 3, a region surrounded by the trench H is one pixel P. The shape of one pixel P in plan view is, for example, a rectangle, and is, for example, a square.

As illustrated in FIGS. 2 and 3, the bottom surface in the trench H is the first insulating film 24. The first protective layer 51 and the second protective layer 52 are disposed in the trench H and cover the side surface of the trench H.

Specifically, the first protective layer 51 continuously covers the side surface of the photoelectric conversion layer 22 and the side surface of the semiconductor layer 23, and reaches the first insulating film 24 which is the bottom surface of the trench H. The second protective layer 52 covers the side surface of the photoelectric conversion layer 22 and the side surface of the semiconductor substrate 21. Furthermore, the second protective layer 52 is covered with the first protective layer 51. The second protective layer 52 is sandwiched between the side surfaces of the photoelectric conversion layer 22 and the semiconductor substrate 21 and the first protective layer 51.

In a case where the photoelectric conversion layer 22 includes InGaAs, the first protective layer 51 preferably includes a metal oxide such as Al₂O₃, AlN, La₂O₃, or MgO. The first protective layer 51 may have a single-layer structure including only one layer of the metal oxide or a multilayer structure (laminated structure) including at least one layer of the metal oxide. For example, the first protective layer 51 includes Al₂O₃. Therefore, the interface state (that is, the interface state of the side surface of the photoelectric conversion layer 22) between the photoelectric conversion layer 22 and the first protective layer 51 can be reduced as compared with a case where the first protective layer 51 includes an insulator such as SiO₂ or SiN.

Furthermore, in a case where the semiconductor substrate 21 includes InP, the second protective layer 52 preferably includes an insulator such as SiO₂ or SiN. The second protective layer 52 may have a single-layer structure including only one layer of the insulator or a multilayer structure (laminated structure) including at least one layer of the insulator. For example, the second protective layer 52 includes SiO₂. Therefore, the interface state (that is, the interface state of the side surface of the semiconductor substrate 21) between the semiconductor substrate 21 and the second protective layer 52 can be reduced as compared with a case where the second protective layer 52 includes a metal oxide such as Al₂O₃, AlN, La2O3, or MgO.

Since the interface state of the side surface of the photoelectric conversion layer 22 and the interface state of the side surface of the semiconductor substrate 21 are reduced, the dark current of the light receiving element 10 can be reduced, and deterioration in the characteristics of the light receiving element 10 can be suppressed.

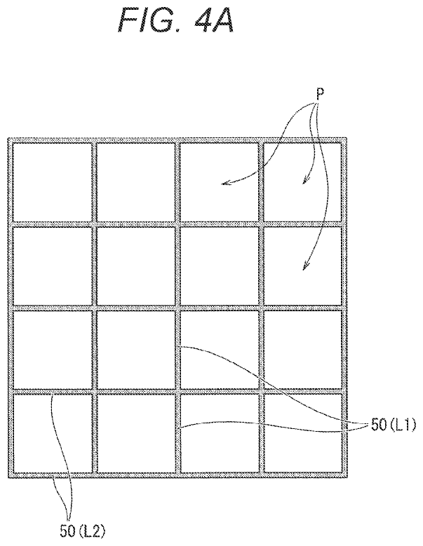

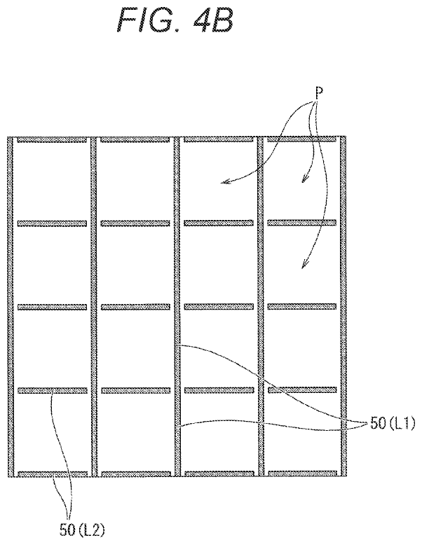

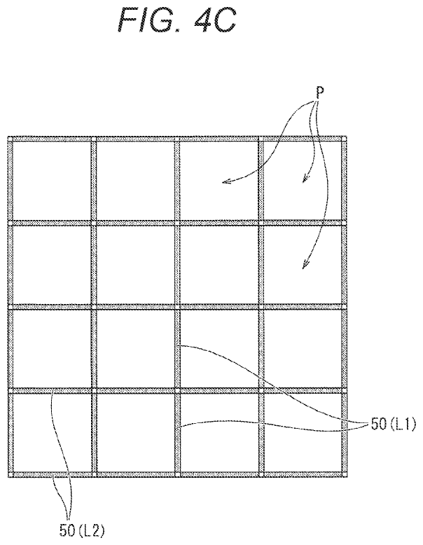

FIGS. 4A to 4C are plan views each illustrating an example of the shape of the pixel isolation portion 50 according to the first embodiment of the present disclosure. As illustrated in FIG. 4A, the shape of the pixel isolation portion 50 in plan view is, for example, a lattice shape. The lattice shape is a shape in which a plurality of first straight line portions L1 extending in one direction is arranged at a constant interval in another direction orthogonal to the one direction, a plurality of second straight line portions L2 extending in the other direction is arranged at a constant interval in the one direction orthogonal to the other direction, and the plurality of first straight line portions L1 and the plurality of second straight line portions L2 intersect each other in plan view.

Note that, as illustrated in FIG. 4B, the pixel isolation portion 50 may have a shape in which one of the first straight line portion L1 and the second straight line portion L2 is continuous and the other is discontinuous in a region where the first straight line portion L1 and the second straight line portion L2 intersect.

Furthermore, as illustrated in FIG. 4C, the pixel isolation portion 50 may have a shape in which both the first straight line portion L1 and the second straight line portion L2 are discontinuous in a region where the first straight line portion L1 and the second straight line portion L2 intersect.

### (Manufacturing Method)

Next, a method for manufacturing the light receiving element 10 illustrated in FIG. 2 will be described. The light receiving element 10 is manufactured by using various devices such as a film formation device (including an epitaxial growth device, a chemical vapor deposition (CVD) device, a sputtering device, and a thermal oxidation device), an exposure device, an etching device, and a CMP device. Hereinafter, these devices are collectively referred to as manufacturing devices. The pixel isolation portion 50 of the light receiving element 10 can be manufactured by a manufacturing method described below.

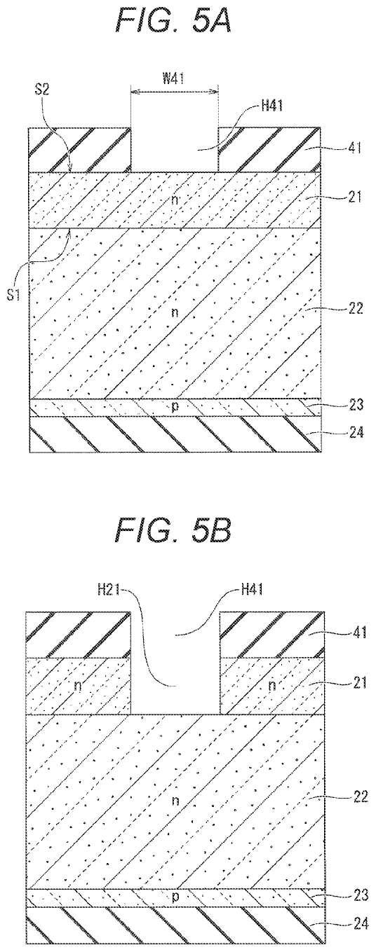

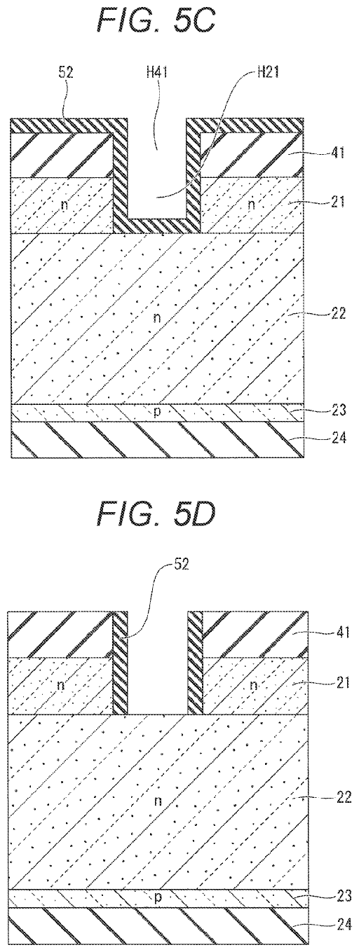

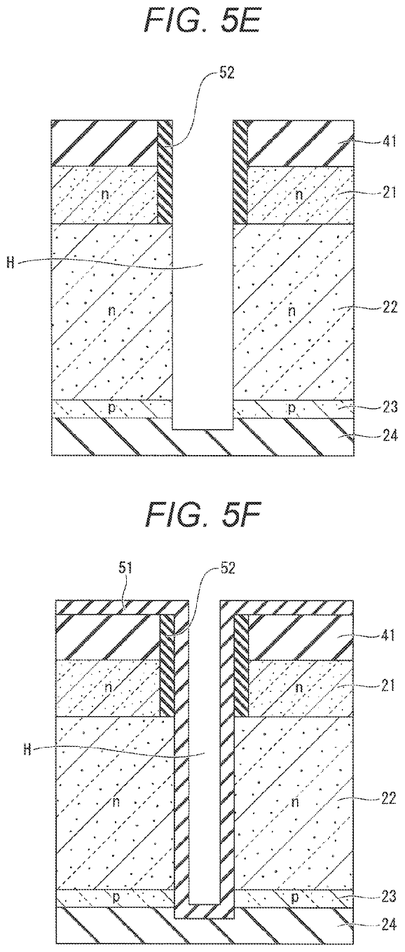

FIGS. 5A to 5F are cross-sectional views illustrating the method for manufacturing the light receiving element 10 according to the first embodiment of the present disclosure in order of process. Here, in particular, a method for manufacturing the pixel isolation portion 50 including the first protective layer 51 and the second protective layer 52 in the light receiving element 10 will be described in order of process.

In FIG. 5A, the manufacturing device forms the photoelectric conversion layer 22, the semiconductor layer 23, and the first insulating film 24 in this order on the first surface S1 of the semiconductor substrate 21. The semiconductor substrate 21 includes, for example, n-type InP. The photoelectric conversion layer 22 includes, for example, n-type InGaAs. The semiconductor layer 23 includes, for example, n-type InP. The photoelectric conversion layer 22 and the semiconductor layer 23 are formed by, for example, an epitaxial growth method. The first insulating film 24 is, for example, a TEOS film.

Furthermore, the manufacturing device forms the second insulating film 41 on the second surface S2 of the semiconductor substrate 21 almost simultaneously with the process of forming the photoelectric conversion layer 22, the semiconductor layer 23, and the first insulating film 24. The second insulating film 41 is, for example, a TEOS film.

Next, the manufacturing device partially etches the second insulating film 41 to form a trench H41. The width W41 of the trench provided in the second insulating film 41 is, for example, 100 nm or more and 400 nm or less.

Next, as illustrated in FIG. 5B, the manufacturing device partially etches the n-type semiconductor substrate 21 by using the second insulating film 41 as a mask to form a trench H21. The trench H21 provided in the semiconductor substrate 21 communicates with the trench H41 of the second insulating film 41.

Next, as illustrated in FIG. 5C, the manufacturing device forms the second protective layer 52, and covers the upper surface of the second insulating film 41, the side surface of the second insulating film 41 facing the trench H41, and the side surface of the semiconductor substrate 21 facing the trench H21 with the second protective layer 52.

Next, the manufacturing device etches back the second protective layer 52. Therefore, as illustrated in FIG. 5D, the second protective layer 52 is removed from the upper surface of the second insulating film 41, and is left on the side surface of the second insulating film 41 and the side surface of the semiconductor substrate 21.

Next, the manufacturing device etches the photoelectric conversion layer 22 and the semiconductor layer 23 by using the second insulating film 41 and the second protective layer 52 as masks. Therefore, as illustrated in FIG. 5E, the trench H penetrating from the second insulating film 41 to the semiconductor layer 23 is formed.

Next, as illustrated in FIG. 5F, the manufacturing device forms the first protective layer 51, and covers the upper surface of the second insulating film 41, the second protective layer 52 left in the trench H, the side surface of the photoelectric conversion layer 22 facing the trench H, the side surface of the semiconductor layer 23 facing the trench H, and the first insulating film 24 located on the bottom surface of the trench H with the first protective layer 51.

Thereafter, the manufacturing device etches back the first protective layer 51. Therefore, the first protective layer 51 is removed from the upper surface of the second insulating film 41 and the bottom surface of the trench H, and is left on the side surface of the trench H. Through such a process, the pixel isolation portion 50 illustrated in FIG. 2 is formed.

Note that, in the process of etching the semiconductor substrate 21 described with reference to FIGS. 5A and 5B, endpoint detection (EPD) may be performed from the optical emission spectroscopy (OES) waveform of the metal, atomic layer etching (ALE) may be performed, or an etching stopper layer may be disposed in advance between the semiconductor substrate 21 and the photoelectric conversion layer 22. Examples of the etching stopper layer include Al-based materials such as InAlAs that can be formed by an epitaxial growth method. Even with such a method, it is possible to etch the semiconductor substrate 21 with high selectivity relative to the photoelectric conversion layer 22.

Furthermore, in the process of etching the photoelectric conversion layer 22 described with reference to FIGS. 5D and 5E, wet etching with a high selectivity, plasma ALE, or thermal ALE may be performed. Even with such a method, it is possible to etch the photoelectric conversion layer 22 with high selectivity relative to the semiconductor substrate 21 and the semiconductor layer 23.

### (Effect of First Embodiment)

As described above, the light receiving element 10 according to the first embodiment of the present disclosure includes the n-type semiconductor substrate 21 (an example of the “support substrate” of the present disclosure) that includes InP (an example of the “first compound semiconductor” of the present disclosure), the photoelectric conversion layer 22 that is provided on the first surface S1 side of the semiconductor substrate 21 and includes InGaAs (an example of the “second compound semiconductor” of the present disclosure), the first protective layer 51 that is provided in the trench H penetrating the semiconductor substrate 21 and the photoelectric conversion layer 22 and is provided on the side surface (an example of the “first side surface” of the present disclosure) of the photoelectric conversion layer 22, and the second protective layer 52 that is provided in the trench H and is provided on the side surface (an example of the “second side surface” of the present disclosure) of the semiconductor substrate 21. The first protective layer 51 and the second protective layer 52 have different compositions. For example, the first protective layer 51 includes Al₂O₃, and the second protective layer 52 includes SiO₂.

An interface state (an example of the “first interface state” in the present disclosure) generated between the side surface of the photoelectric conversion layer 22 and the first protective layer 51 is smaller than an interface state generated between the side surface of the photoelectric conversion layer 22 and the second protective layer 52 in a case where the second protective layer 52 is in contact with the side surface of the photoelectric conversion layer 22. An interface state (an example of the “second interface state” in the present disclosure) generated between the side surface of the semiconductor substrate 21 and the second protective layer 52 is smaller than an interface state generated between the side surface of the semiconductor substrate 21 and the first protective layer 51 in a case where the first protective layer 51 is in contact with the side surface of the semiconductor substrate 21.

According to this, it is possible to select an optimum protective layer for each of the side surface of the photoelectric conversion layer 22 and the side surface of the semiconductor substrate 21. Therefore, it is possible to reduce interface states of both the side surface of the photoelectric conversion layer 22 and the side surface of the semiconductor substrate 21 as compared with a case where one type of film having the same composition is formed as a protective layer on the side surface of the photoelectric conversion layer 22 and on the side surface of the semiconductor substrate 21. Therefore, for example, since dark current can be reduced, deterioration in the characteristics of the light receiving element 10 can be suppressed.

### (Modification)

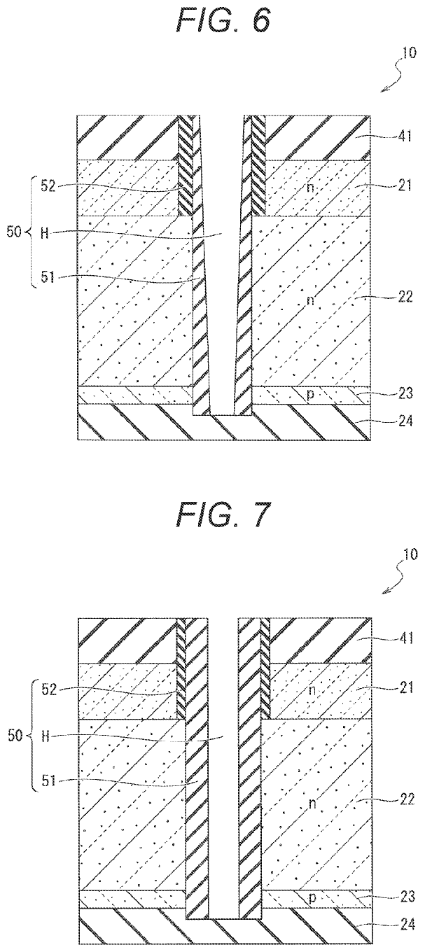

FIG. 6 is a cross-sectional view illustrating a first modification of the pixel isolation portion 50 of the light receiving element 10 according to the first embodiment of the present disclosure. As illustrated in FIG. 6, the first protective layer 51 may have a configuration in which the thickness on the opening side of the trench H is thin and the thickness gradually increases toward the bottom surface (that is, the first insulating film 24) of the trench H.

The first protective layer 51 having such a shape can be formed by etching the first protective layer 51 by using a mask or etching back the first protective layer 51 after forming the first protective layer 51 on the entire surface. Even with such a configuration, similarly to the case of the pixel isolation portion 50 illustrated in FIG. 2, the interface state of the side surface of the photoelectric conversion layer 22 and the interface state of the side surface of the semiconductor substrate 21 can be reduced.

FIG. 7 is a cross-sectional view illustrating a second modification of the pixel isolation portion 50 of the light receiving element 10 according to the first embodiment of the present disclosure. As illustrated in FIG. 7, the first protective layer 51 may be thick, and the second protective layer 52 may be thin. That is, the film thickness of the first protective layer 51 may be thicker than the film thickness of the second protective layer 52. Even with such a configuration, similarly to the case of the pixel isolation portion 50 illustrated in FIG. 2, the interface state of the side surface of the photoelectric conversion layer 22 and the interface state of the side surface of the semiconductor substrate 21 can be reduced.

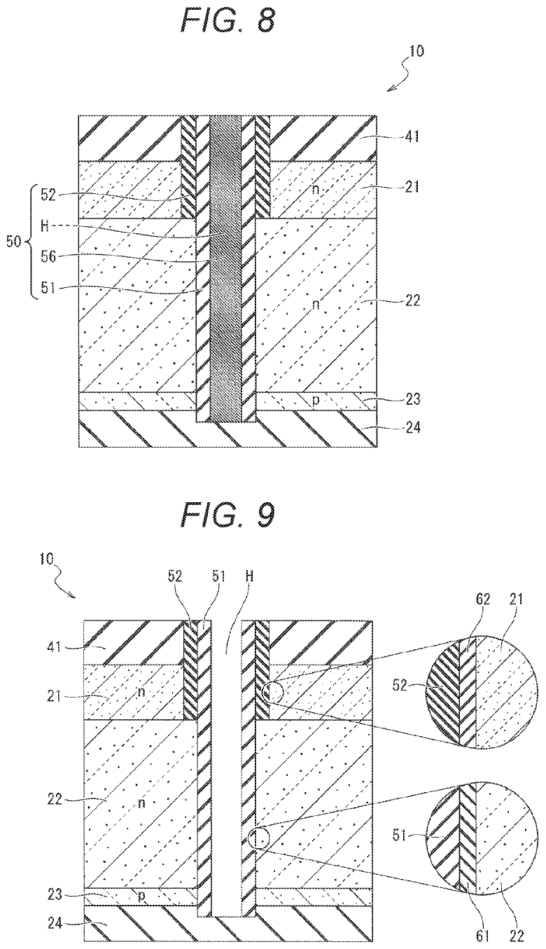

FIG. 8 is a cross-sectional view illustrating a third modification of the pixel isolation portion 50 of the light receiving element 10 according to the first embodiment of the present disclosure. As illustrated in FIG. 8, the pixel isolation portion 50 may have a conductive layer 56 disposed (embedded) in the trench H. The conductive layer 56 preferably has a light shielding property, for example, similarly to the light shielding layer 55 illustrated in FIG. 2.

Even with such a configuration, similarly to the case of the pixel isolation portion 50 illustrated in FIG. 2, the interface state of the side surface of the photoelectric conversion layer 22 and the interface state of the side surface of the semiconductor substrate 21 can be reduced. Furthermore, by applying a voltage to the conductive layer 56, carriers generated from crystal defects can be fixed on the side surfaces of the photoelectric conversion layer 22, the semiconductor substrate 21, and the semiconductor layer 23. That is, the surface pinning effect can be obtained.

Note that, in a case where the pixel isolation portion 50 includes the conductive layer 56 and a voltage is applied to the conductive layer 56, the first protective layer 51 and the second protective layer 52 preferably have a high withstand voltage and are thin films in order to obtain a voltage application effect.

FIG. 9 is a cross-sectional view illustrating a fourth modification of the pixel isolation portion 50 of the light receiving element 10 according to the first embodiment of the present disclosure. As illustrated in FIG. 9, a first intermediate layer 61 may be provided between the side surface of the photoelectric conversion layer 22 and the first protective layer 51. The first intermediate layer 61 may be, for example, an oxide layer formed by thermally oxidizing the photoelectric conversion layer 22. As an example, in a case where the photoelectric conversion layer 22 includes InGaAs, the first intermediate layer 61 may include Ga₂O₃ formed by thermally oxidizing InGaAs.

Similarly, a second intermediate layer 62 may be provided between the side surface of the semiconductor substrate 21 and the second protective layer 52. The second intermediate layer 62 may be, for example, an oxide layer formed by thermally oxidizing the semiconductor substrate 21. As an example, in a case where the semiconductor substrate 21 includes InP, the second intermediate layer 62 may include In₂O₃ formed by thermally oxidizing InP.

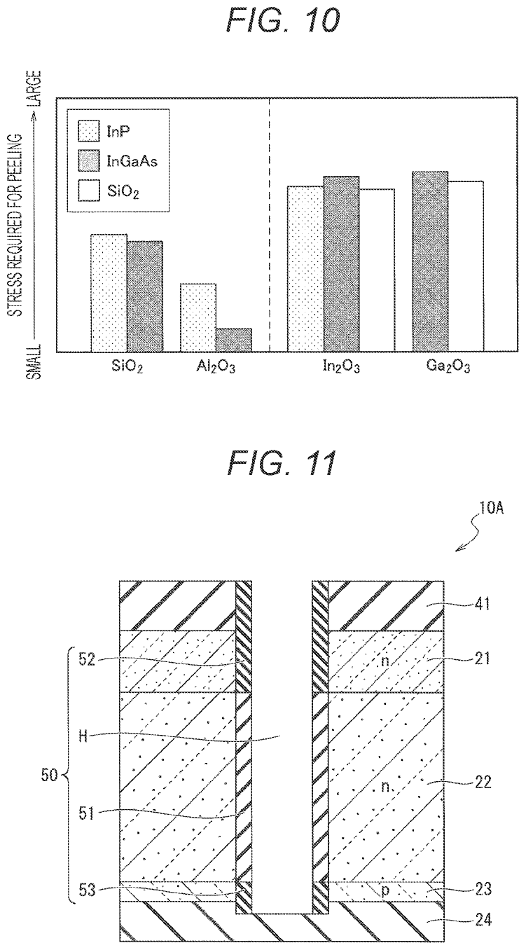

FIG. 10 is a graph illustrating results of simulating interface adhesion. In FIG. 10, the horizontal axis represents the material of the base film, and the vertical axis represents the stress required for peeling each film illustrated in FIG. 10 from the base film.

As illustrated in FIG. 10, stress required for peeling Ga₂O₃ from InGaAs is larger than stress required for peeling Al₂O₃ from InGaAs. Furthermore, although not illustrated in FIG. 10, stress necessary for peeling Al₂O₃ from Ga₂O₃ is larger than stress necessary for peeling Al₂O₃ from InGaAs. Therefore, in a case where the photoelectric conversion layer 22 includes InGaAs and the first protective layer 51 includes Al₂O₃, Ga₂O₃ exists as the first intermediate layer 61 between the photoelectric conversion layer 22 and the first protective layer 51, so that stress necessary for peeling the first protective layer 51 from the photoelectric conversion layer 22 can be increased, and adhesion between the photoelectric conversion layer 22 and the first protective layer 51 can be enhanced.

That is, the bonding force between the side surface of the photoelectric conversion layer 22 and the first protective layer 51 with the first intermediate layer 61 interposed therebetween is larger than the bonding force of the side surface of the photoelectric conversion layer 22 with the first protective layer 51 in a case where the first protective layer 51 is directly in contact with the side surface of the photoelectric conversion layer 22 without the first intermediate layer 61 interposed therebetween. Therefore, the first intermediate layer 61 exists between the side surface of the photoelectric conversion layer 22 and the first protective layer 51, so that the bonding force between the side surface of the photoelectric conversion layer 22 and the first protective layer 51 can be enhanced, and the adhesion between the side surface of the photoelectric conversion layer 22 and the first protective layer 51 can be enhanced.

Similarly, as illustrated in FIG. 10, stress necessary for peeling InP from In₂O₃ is larger than stress necessary for peeling InP from SiO₂. Furthermore, stress necessary for peeling SiO₂ from In₂O₃ is larger than stress necessary for peeling InP from SiO₂. Therefore, in a case where the semiconductor substrate 21 includes InP and the second protective layer 52 includes SiO₂, In₂O₃ exists as the second intermediate layer 62 between the semiconductor substrate 21 and the second protective layer 52, so that stress necessary for peeling the second protective layer 52 from the semiconductor substrate 21 can be increased, and adhesion between the semiconductor substrate 21 and the second protective layer 52 can be enhanced.

That is, the bonding force between the side surface of the semiconductor substrate 21 and the second protective layer 52 with the second intermediate layer 62 interposed therebetween is larger than the bonding force between the side surface of the semiconductor substrate 21 and the second protective layer 52 in a case where the second protective layer 52 is directly in contact with the side surface of the semiconductor substrate 21 without the second intermediate layer 62 interposed therebetween. Therefore, the second intermediate layer 62 exists between the side surface of the semiconductor substrate 21 and the second protective layer 52, so that the bonding force between the side surface of the semiconductor substrate 21 and the second protective layer 52 can be enhanced, and the adhesion between the side surface of the semiconductor substrate 21 and the second protective layer 52 can be enhanced.

### Second Embodiment

### (Configuration Example of Pixel Isolation Portion)

FIG. 11 is a cross-sectional view illustrating a configuration example of a pixel isolation portion 50 of a light receiving element 10A according to a second embodiment of the present disclosure. The light receiving element 10A illustrated in FIG. 11 is different from the light receiving element 10 illustrated in FIG. 2 in the configuration of the pixel isolation portion 50. In the second embodiment, the pixel isolation portion 50 includes a first protective layer 51, a second protective layer 52, and a third protective layer 53 disposed in a trench H. In the trench H, the first protective layer 51 covers the side surface of a photoelectric conversion layer 22, the second protective layer 52 covers the side surface of a semiconductor substrate 21, and the third protective layer 53 covers the side surface of a semiconductor layer 23. The third protective layer 53 is in contact with a first insulating film 24 which is the bottom surface of the trench H.

Furthermore, in the trench H, the first protective layer 51 does not cover the second protective layer 52. There is no step between the side surface of the semiconductor substrate 21 and the side surface of the photoelectric conversion layer 22 (alternatively, even if there is a step, the size is very small), and the side surface of the semiconductor substrate 21, the side surface of the photoelectric conversion layer 22, and the side surface of the semiconductor layer 23 are flush (or substantially flush) with one another.

In a case where the semiconductor layer 23 includes InP, the third protective layer 53 preferably includes an insulator such as SiO₂ or SiN. The third protective layer 53 may have a single-layer structure including only one layer of the insulator or a multilayer structure (laminated structure) including at least one layer of the insulator. For example, the third protective layer 53 includes SiO₂. Therefore, the interface state (that is, the interface state of the side surface of the semiconductor layer 23) between the semiconductor layer 23 and the third protective layer 53 can be reduced as compared with a case where the third protective layer 53 includes a metal oxide such as Al₂O₃, AlN, La₂O₃, or MgO.

### (Manufacturing Method)

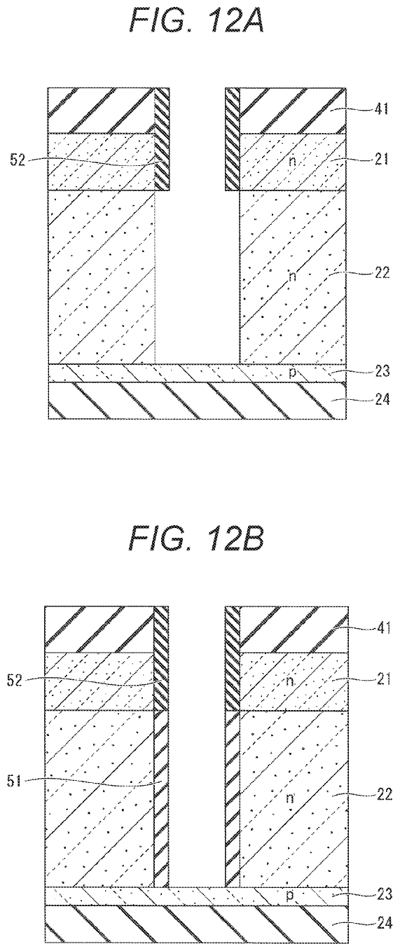

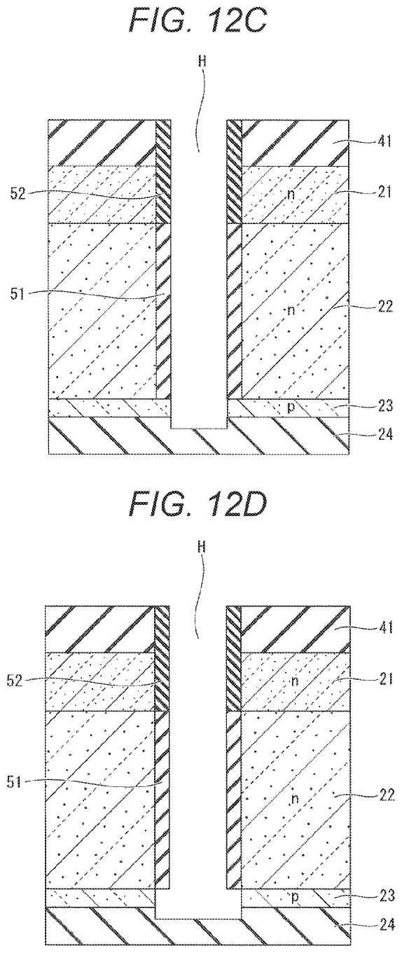

Next, a method for manufacturing the light receiving element 10A illustrated in FIG. 2 will be described. FIGS. 12A to 12D are cross-sectional views illustrating a method for manufacturing the light receiving element 10A according to the second embodiment of the present disclosure in order of process. In FIG. 12A, the processes up to the process of forming the second protective layer 52 in the trench H are the same as those of the method for manufacturing the light receiving element 10 illustrated in FIGS. 5A to 5E.

After the second protective layer 52 is formed, the manufacturing device etches the side surface of the photoelectric conversion layer 22 to make the side surface of the photoelectric conversion layer 22 flush (or substantially flush) with the side surface of the semiconductor substrate 21. In this process, the side surface of the photoelectric conversion layer 22 may be etched by using the second protective layer 52 as a mask.

Next, as illustrated in FIG. 12B, the manufacturing device forms the first protective layer 51 on the side surface of the photoelectric conversion layer 22. The first protective layer 51 may be formed by a selective epitaxial growth method in which a film is formed only on the side surface of the photoelectric conversion layer 22, may be formed by an atomic layer deposition (selective ALD) method in which a film is formed only on the side surface of the photoelectric conversion layer 22, may be formed by performing ion beam etching or the like after forming a film on the entire surface, or may be formed by performing atomic layer etching (ALE) after performing atomic layer volume (ALD).

Next, as illustrated in FIG. 12C, the manufacturing device etches and removes the semiconductor layer 23 located on the bottom surface of the trench H, and causes the trench H to reach the first insulating film 24.

Next, as illustrated in FIG. 12D, the manufacturing device etches the side surface of the semiconductor layer 23 to make the side surface of the semiconductor layer 23 flush (or substantially flush) with the side surface of the photoelectric conversion layer 22. In this process, the side surface of the semiconductor layer 23 may be etched by using the first protective layer 51 and the second protective layer 52 as masks. Furthermore, FIGS. 12C and 12D may be performed in one continuous etching process.

Thereafter, the manufacturing device forms the third protective layer 53 on the entire surface, and etches back the third protective layer 53 to form the third protective layer 53 (see FIG. 11) on the side surface of the semiconductor layer 23. Alternatively, the third protective layer 53 may be formed by performing ion beam etching or the like after forming a film on the entire surface. Through such processes, the pixel isolation portion 50 illustrated in FIG. 11 is formed.

### (Effects of Second Embodiment)

The light receiving element 10A has effects similar to those of the light receiving element 10 illustrated in FIG. 2. Furthermore, in the light receiving element 10A, not only the interface state of the side surface of the photoelectric conversion layer 22 and the interface state of the side surface of the semiconductor substrate 21 but also the interface state of the side surface of the semiconductor layer 23 are reduced. As a result, the light receiving element 10A can further reduce dark current, and can further suppress deterioration in characteristics.

### (Modification)

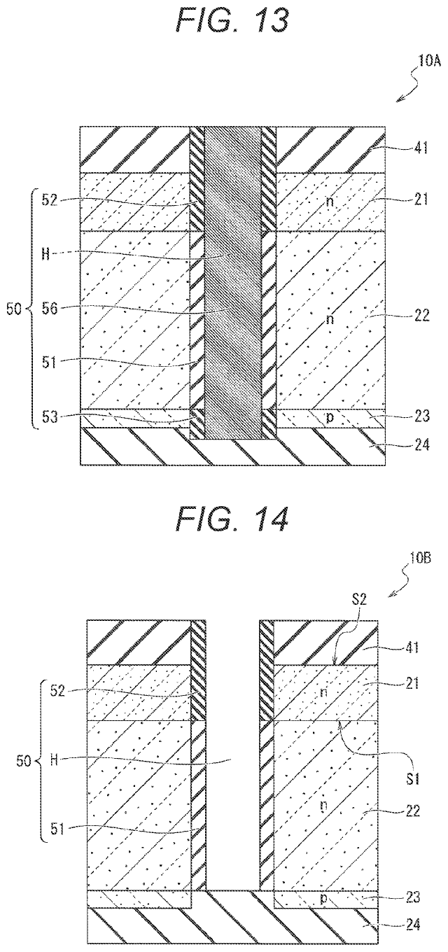

FIG. 13 is a cross-sectional view illustrating a modification of the pixel isolation portion 50 of the light receiving element 10A according to the second embodiment of the present disclosure. As illustrated in FIG. 13, also in the light receiving element 10A according to the second embodiment, the pixel isolation portion 50 may include a conductive layer 56 disposed in the trench H.

With such a configuration, by applying a voltage to the conductive layer 56, carriers generated from crystal defects can be fixed on the side surfaces of the photoelectric conversion layer 22, the semiconductor substrate 21, and the semiconductor layer 23, and a surface pinning effect can be obtained.

Moreover, in the trench H, since the first protective layer 51 does not cover the second protective layer 52, the film thickness of the protective layer that covers the side surface of the semiconductor substrate 21 can be reduced. Therefore, the voltage application effect on the side surface of the semiconductor substrate 21 can be enhanced, and the surface pinning effect on the side surface of the semiconductor substrate 21 can be further enhanced.

### Third Embodiment

### (Configuration Example of Pixel Isolation Portion)

FIG. 14 is a cross-sectional view illustrating a configuration example of a pixel isolation portion 50 of a light receiving element 10B according to a third embodiment of the present disclosure. As illustrated in FIG. 14, in the light receiving element 10B, a trench H penetrates a semiconductor layer 23, and a portion of the trench H penetrating the semiconductor layer 23 is filled with a first insulating film 24. In the trench H, the side surface of the semiconductor layer 23 is covered with the first insulating film 24. This structure can be formed by etching the semiconductor layer 23 from the side (in FIG. 14, the lower side) of the semiconductor layer 23 opposite to the surface of the semiconductor layer 23 in contact with a photoelectric conversion layer 22.

### (Manufacturing Method)

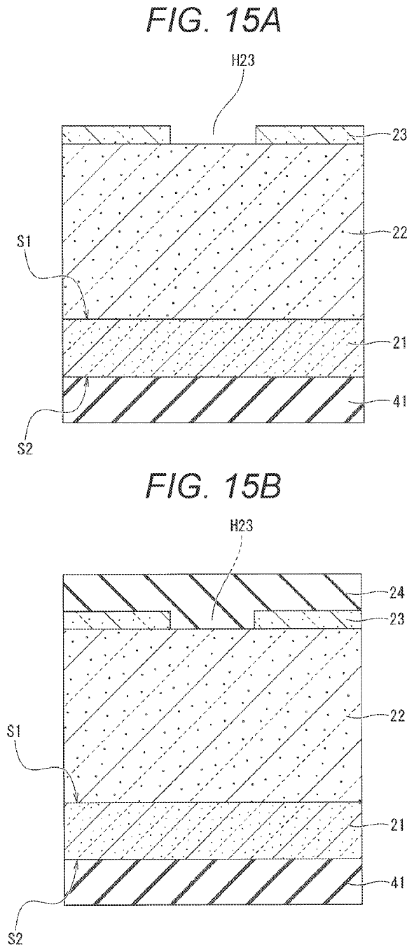

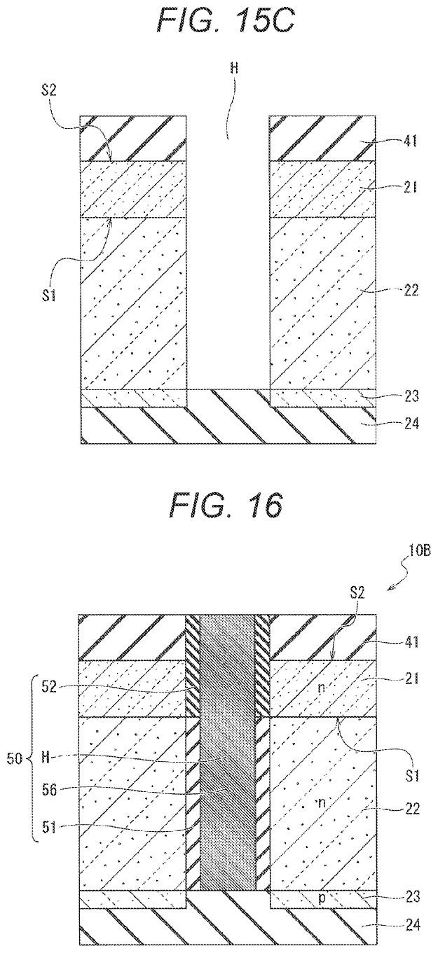

FIGS. 15A to 15C are cross-sectional views illustrating a method for manufacturing the light receiving element 10B according to the third embodiment of the present disclosure in order of process. In FIG. 15A, a first surface S1 of the semiconductor substrate 21 faces upward, and a second surface S2 faces downward. In this state, the manufacturing device partially etches the semiconductor layer 23 to form a trench H23. Next, as illustrated in FIG. 15B, the manufacturing device forms the first insulating film 24 on the semiconductor layer 23 and fills the trench H23.

Next, as illustrated in FIG. 15C, the manufacturing device sequentially etches the second insulating film 41, the semiconductor substrate 21, and the photoelectric conversion layer 22 in a state where the upper and lower sides of the semiconductor substrate 21 are switched (that is, in a state where the first surface S1 faces downward and the second surface S2 faces upward,) as illustrated in FIG. 15C. In etching of the photoelectric conversion layer 22, the first insulating film 24 serves as an etching stopper. Therefore, the trench H is formed.

Thereafter, the second protective layer 52 is formed on the side surface of the semiconductor substrate 21. Furthermore, the first protective layer 51 is formed on the side surface of the photoelectric conversion layer 22 almost simultaneously with the process of forming the second protective layer 52. In the process of forming the second protective layer 52, it is preferable to cover the side surface of the photoelectric conversion layer 22 with an insulating film or the like (that is, it is preferable that the exposed surface is only the side surface of the semiconductor substrate 21). Therefore, when the second protective layer 52 is formed, it is possible to suppress the occurrence of unintended elimination or intrusion of an element in the side surface of the photoelectric conversion layer 22. Similarly, in the process of forming the first protective layer 51, it is preferable to cover the side surface of the semiconductor substrate 21 with an insulating film or the like (that is, it is preferable that the exposed surface is only the side surface of the photoelectric conversion layer 22). Therefore, when the first protective layer 51 is formed, it is possible to suppress the occurrence of unintended elimination or intrusion of an element in the side surface of the semiconductor substrate 21.

The side surface of the semiconductor layer 23 (for example, InP) is covered with the first insulating film 24. As a result, when the first protective layer 51 and the second protective layer 52 are formed, it is possible to suppress unintended intrusion or elimination of an element in the side surface of the semiconductor layer 23 without performing special processing. Through such processes, the pixel isolation portion 50 illustrated in FIG. 14 is formed.

Note that in a case where the photoelectric conversion layer 22 includes InGaAs, there is a possibility that dark current increases on the surface of InGaAs due to As-As coupling. As a result, after the trench H is formed, wet processing may be performed on the side surface of the photoelectric conversion layer 22 to remove As. At that time, in order to prevent intrusion of As into the semiconductor substrate 21 (for example, InP), it is preferable to cover the side surface of the semiconductor substrate 21 (that is, it is preferable that the exposed surface is only the side surface of the photoelectric conversion layer 22).

The side surface of the semiconductor layer 23 (for example, InP) is covered with the first insulating film 24. As a result, in the wet processing described above, the intrusion of As into the side surface of the semiconductor layer 23 is suppressed without performing special processing.

### (Effect of Third Embodiment)

The light receiving element 10B exhibits an effect of reducing the interface state for the side surface of the photoelectric conversion layer 22 and the side surface of the semiconductor substrate 21, for example, similarly to the light receiving element 10 illustrated in FIG. 2. Furthermore, similarly to the light receiving element 10A illustrated in FIG. 11, since the film thickness of the protective layer covering the side surface of the semiconductor substrate 21 can be reduced, the voltage application effect on the side surface of the semiconductor substrate 21 can be enhanced, and a surface pinning effect on the side surface of the semiconductor substrate 21 can be further enhanced.

### (Modification)

FIG. 16 is a cross-sectional view illustrating a modification of the pixel isolation portion 50 of the light receiving element 10B according to the third embodiment of the present disclosure. As illustrated in FIG. 16, also in the light receiving element 10B according to the third embodiment, the pixel isolation portion 50 may include a conductive layer 56 disposed in the trench H.

With such a configuration, by applying a voltage to the conductive layer 56, carriers generated from crystal defects can be fixed on the side surface of the photoelectric conversion layer 22 and the side surface of the semiconductor substrate 21. That is, the surface pinning effect can be obtained.

### Fourth Embodiment

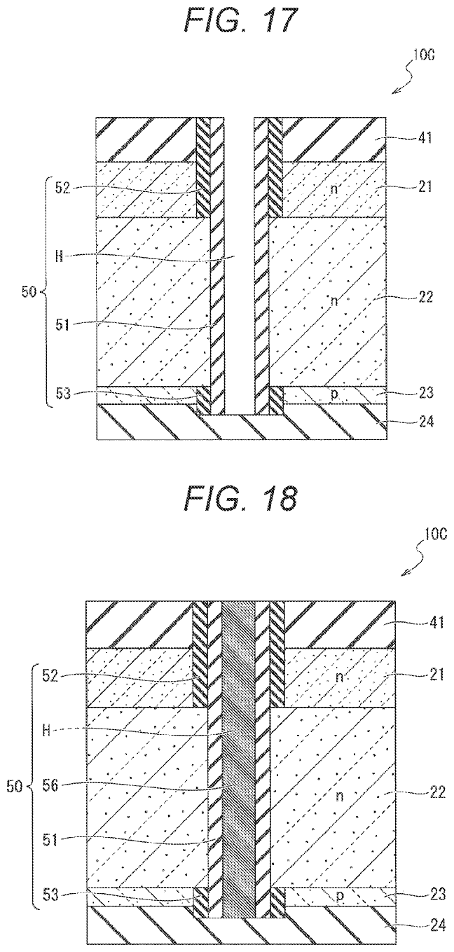

FIG. 17 is a cross-sectional view illustrating a configuration example of a pixel isolation portion 50 of a light receiving element 10C according to a fourth embodiment of the present disclosure. As illustrated in FIG. 17, in a trench H, a first protective layer 51 covers the side surface of a semiconductor substrate 21 with a second protective layer 52 interposed therebetween. Furthermore, the first protective layer 51 covers a semiconductor layer 23 with a third protective layer 53 interposed therebetween. The light receiving element 10C having such a configuration exhibits an effect of reducing the interface state for the side surface of a photoelectric conversion layer 22 and the side surface of the semiconductor substrate 21, for example, similarly to the light receiving element 10A illustrated in FIG. 11.

FIG. 18 is a cross-sectional view illustrating a modification of the pixel isolation portion 50 of the light receiving element 10C according to the fourth embodiment of the present disclosure. As illustrated in FIG. 18, also in the light receiving element 10C according to the fourth embodiment, the pixel isolation portion 50 may include a conductive layer 56 disposed in the trench H. With such a configuration, by applying a voltage to the conductive layer 56, carriers generated from crystal defects can be fixed on the side surfaces of the photoelectric conversion layer 22, the semiconductor substrate 21, and the semiconductor layer 23, and a surface pinning effect can be obtained.

### Fifth Embodiment

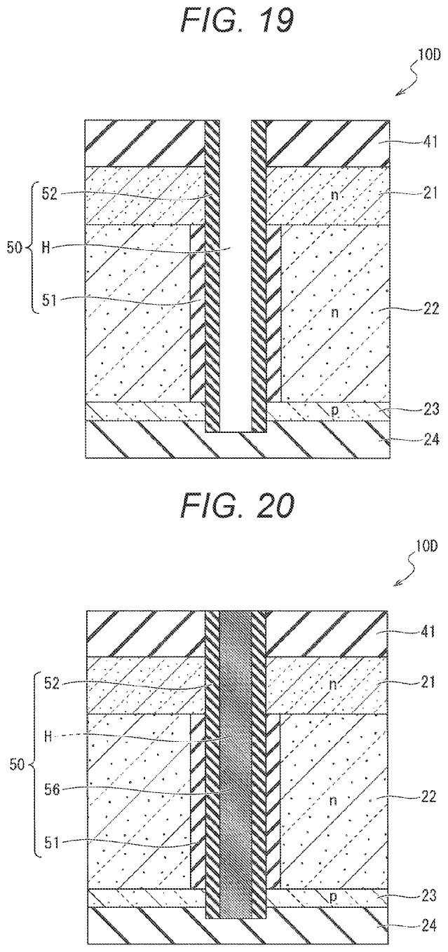

FIG. 19 is a cross-sectional view illustrating a configuration example of a pixel isolation portion 50 of a light receiving element 10D according to a fifth embodiment of the present disclosure. As illustrated in FIG. 19, in a trench H, a second protective layer 52 covers the side surface of a photoelectric conversion layer 22 with a first protective layer 51 interposed therebetween. The light receiving element 10D having such a configuration exhibits an effect of reducing the interface state for the side surface of the photoelectric conversion layer 22 and the side surface of a semiconductor substrate 21, for example, similarly to the light receiving element 10A illustrated in FIG. 11.

FIG. 20 is a cross-sectional view illustrating a modification of the pixel isolation portion 50 of the light receiving element 10D according to the fifth embodiment of the present disclosure. As illustrated in FIG. 20, also in the light receiving element 10D according to the fifth embodiment, the pixel isolation portion 50 may include a conductive layer 56 disposed in the trench H. With such a configuration, by applying a voltage to the conductive layer 56, carriers generated from crystal defects can be fixed on the side surfaces of the photoelectric conversion layer 22, the semiconductor substrate 21, and the semiconductor layer 23, and a surface pinning effect can be obtained.

### Sixth Embodiment

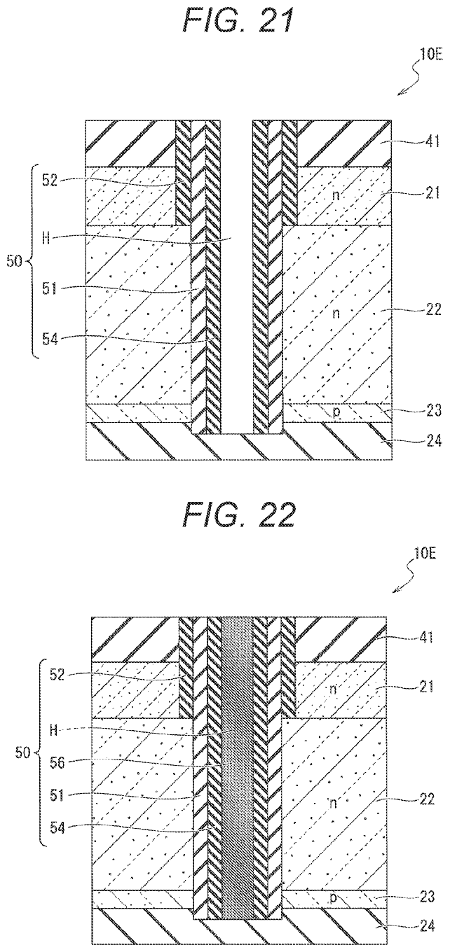

FIG. 21 is a cross-sectional view illustrating a configuration example of a pixel isolation portion 50 of a light receiving element 10E according to a sixth embodiment of the present disclosure. As illustrated in FIG. 21, the pixel isolation portion 50 includes a fourth protective layer 54 that is provided in a trench H and covers a first protective layer 51. The film type of the fourth protective layer 54 is not particularly limited, and is, for example, an insulating film including SiO₂, SiN, or the like. The light receiving element 10E having such a configuration exhibits an effect of reducing the interface state for the side surface of a photoelectric conversion layer 22 and the side surface of a semiconductor substrate 21, for example, similarly to the light receiving element 10 illustrated in FIG. 2.

FIG. 22 is a cross-sectional view illustrating a modification of the pixel isolation portion 50 of the light receiving element 10E according to the sixth embodiment of the present disclosure. As illustrated in FIG. 22, also in the light receiving element 10E according to the sixth embodiment, the pixel isolation portion 50 may include a conductive layer 56 disposed in the trench H. With such a configuration, by applying a voltage to the conductive layer 56, carriers generated from crystal defects can be fixed on the side surfaces of the photoelectric conversion layer 22, the semiconductor substrate 21, and the semiconductor layer 23, and a surface pinning effect can be obtained.

### Seventh Embodiment

FIG. 23 is a cross-sectional view illustrating a configuration example of a pixel isolation portion 50 of a light receiving element 10F according to a seventh embodiment of the present disclosure. As illustrated in FIG. 23, in a trench H, the side surface of a semiconductor layer 23 is covered with a first insulating film 24. Furthermore, the pixel isolation portion 50 includes a fourth protective layer 54 that is provided in the trench H and covers a first protective layer 51. That is, the light receiving element 10F has a configuration in which the light receiving element 10C (see FIG. 14) according to the third embodiment and the light receiving element 10E (see FIG. 21) according to the sixth embodiment are combined. The light receiving element 10F having such a configuration exhibits an effect of reducing the interface state for the side surface of a photoelectric conversion layer 22 and the side surface of a semiconductor substrate 21, for example, similarly to the light receiving element 10 illustrated in FIG. 2.

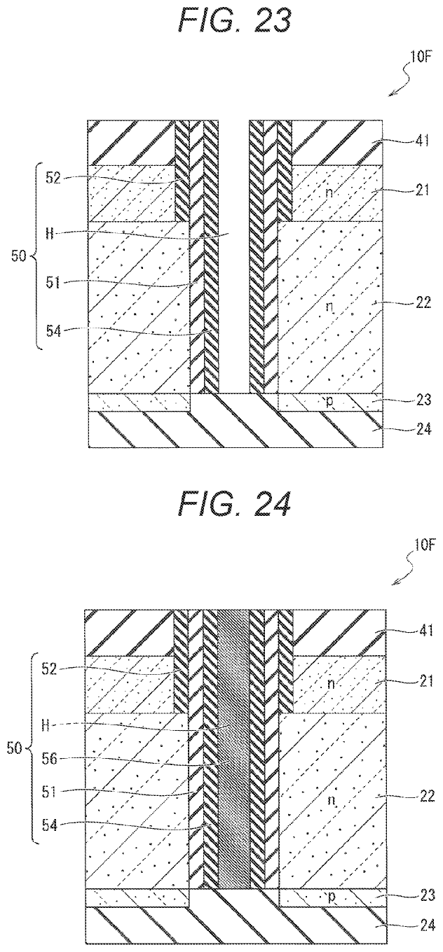

FIG. 24 is a cross-sectional view illustrating a modification of the pixel isolation portion 50 of the light receiving element 10F according to the seventh embodiment of the present disclosure. As illustrated in FIG. 24, also in the light receiving element 10F according to the seventh embodiment, the pixel isolation portion 50 may include a conductive layer 56 disposed in the trench H. With such a configuration, by applying a voltage to the conductive layer 56, carriers generated from crystal defects can be fixed on the side surfaces of the photoelectric conversion layer 22 and the semiconductor substrate 21, and a surface pinning effect can be obtained.

### Eighth Embodiment

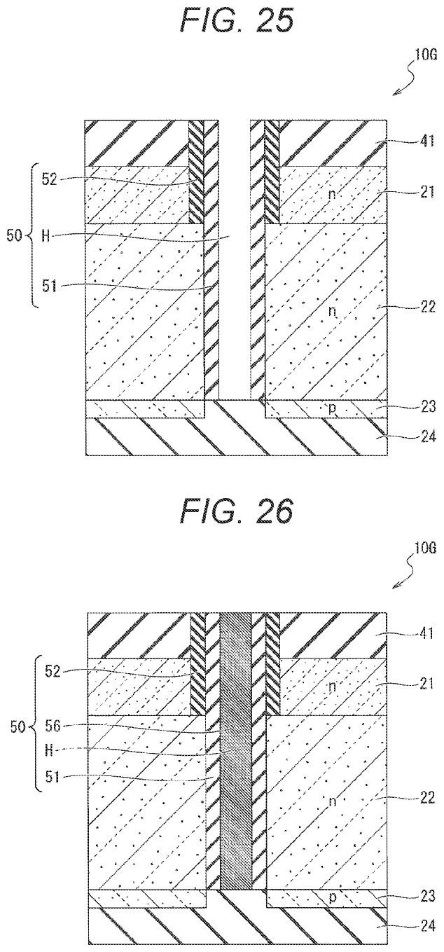

FIG. 25 is a cross-sectional view illustrating a configuration example of a pixel isolation portion 50 of a light receiving element 10G according to an eighth embodiment of the present disclosure. As illustrated in FIG. 25, in the light receiving element 10G, a second protective layer 52 covers the side surface of a semiconductor substrate 21. The first protective layer 51 covers the side surface of a photoelectric conversion layer 22 and the second protective layer 52. Furthermore, in a trench H, the side surface of a semiconductor layer 23 is covered with a first insulating film 24. That is, the light receiving element 10G has a configuration in which the light receiving element 10 (see FIG. 2) according to the first embodiment and the light receiving element 10C (see FIG. 14) according to the third embodiment are combined. The light receiving element 10G having such a configuration exhibits an effect of reducing the interface state for the side surface of the photoelectric conversion layer 22 and the side surface of the semiconductor substrate 21, for example, similarly to the light receiving element 10 illustrated in FIG. 2.

FIG. 26 is a cross-sectional view illustrating a modification of the pixel isolation portion 50 of the light receiving element 10G according to the eighth embodiment of the present disclosure. As illustrated in FIG. 26, also in the light receiving element 10G according to the eighth embodiment, the pixel isolation portion 50 may include a conductive layer 56 disposed in the trench H. With such a configuration, by applying a voltage to the conductive layer 56, carriers generated from crystal defects can be fixed on the side surfaces of the photoelectric conversion layer 22 and the semiconductor substrate 21, and a surface pinning effect can be obtained.

### <Imaging Device>

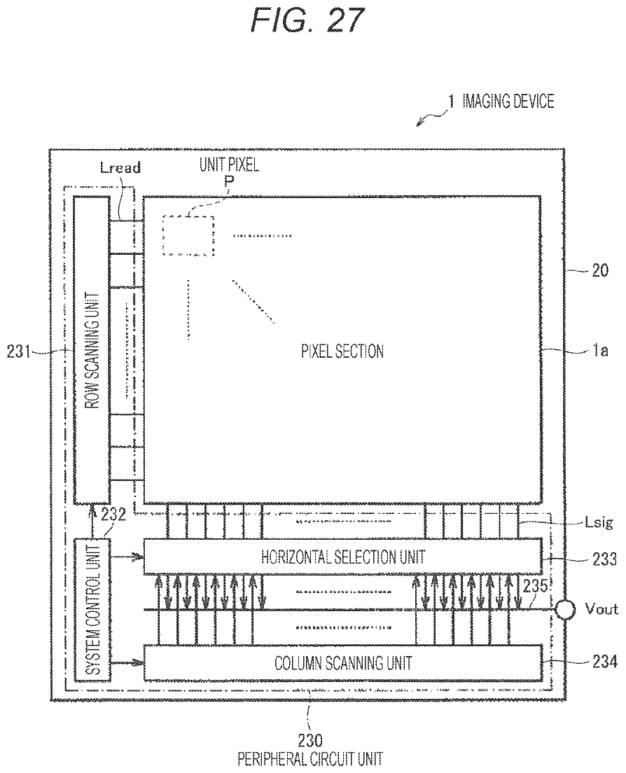

FIG. 27 is a diagram illustrating a functional configuration example of an imaging device 1 using any one or more of the light receiving elements 10, 10A to 10G described in the respective embodiments described above. As illustrated in FIG. 27, the imaging device 1 according to an embodiment of the present disclosure is, for example, an infrared image sensor, and includes, on a substrate 20, a pixel portion 1a and a peripheral circuit unit 230 that drives the pixel portion 1a. The peripheral circuit unit 230 includes a row scanning unit 231, a horizontal selection unit 233, a column scanning unit 234, and a system control unit 232.

The pixel portion 1a includes a plurality of pixels P two-dimensionally arranged in a matrix. In the pixels P, a pixel drive line Lread (for example, a row selection line and a reset control line) is wired for each pixel row, and a vertical signal line Lsig is wired for each pixel column. The pixel drive line Lread transmits a drive signal for reading a signal from the pixel P. One end of the pixel drive line Lread is connected to an output end corresponding to a row of the row scanning unit 231.

The row scanning unit 231 includes a shift register, an address decoder, and the like, and is a pixel drive unit that drives the pixels P of the pixel portion 1a row by row. Signals output from the pixels P of the pixel row selectively scanned by the row scanning unit 231 are supplied to the horizontal selection unit 233 through the vertical signal lines Lsig. The horizontal selection unit 233 includes an amplifier, a horizontal selection switch, and the like provided for each vertical signal line Lsig.

The column scanning unit 234 includes a shift register, an address decoder, and the like, and scans and concurrently drives the horizontal selection switches of the horizontal selection unit 233 in order. By selective scanning by the column scanning unit 234, the signals of the pixels transmitted through the vertical signal lines Lsig are output to a horizontal signal line 235 in order, and input to a signal processing unit or the like, not illustrated, through the horizontal signal line 235.

The system control unit 232 receives an externally supplied clock, data instructing an operation mode and the like, and furthermore outputs data such as internal information of the imaging device 1. The system control unit 232 further includes a timing generator that generates various timing signals, and performs drive control of the row scanning unit 231, the horizontal selection unit 233, the column scanning unit 234, and the like on the basis of the various timing signals generated by the timing generator.

### Other Embodiments

As described above, the present disclosure is described according to the embodiments and modifications thereof, but it should not be understood that the description and drawings forming a part of this disclosure limit the present disclosure. Various alternative embodiments, examples, and operation techniques will be apparent to those skilled in the art from this disclosure. For example, in the embodiments described above, a case where the first conductivity type is the n-type and the second conductivity type is the p-type has been described; however, the present disclosure is not limited thereto. In the present disclosure, the first conductivity type may be the p-type and the second conductivity type may be the n-type. It is a matter of course that the technology according to the present disclosure (present technology) includes various embodiments and the like not described herein. At least one of various omissions, substitutions, or changes of the components may be made without departing from the gist of the above-described embodiments. Furthermore, the effect described in the present description is illustrative only; the effect is not limited thereto and there may also be another effect.

Note that the present disclosure can also have the following configurations.

(1)

An imaging device including:

a support substrate that includes a first compound semiconductor;

a photoelectric conversion layer that is provided on a first surface side of the support substrate and includes a second compound semiconductor having a composition different from a composition of the first compound semiconductor;

a first protective layer that is provided in a trench penetrating the support substrate and the photoelectric conversion layer and is provided on a first side surface of the photoelectric conversion layer; and

a second protective layer that is provided in the trench and is provided on a second side surface of the support substrate,

the first protective layer and the second protective layer having different compositions,

a first interface state generated between the first side surface and the first protective layer being smaller than an interface state generated between the first side surface and the second protective layer in a case where the second protective layer is in contact with the first side surface, and

a second interface state generated between the second side surface and the second protective layer being smaller than an interface state generated between the second side surface and the first protective layer in a case where the first protective layer is in contact with the second side surface.

(2)

The imaging device according to (1) further including

a plurality of pixels,

in which the support substrate and the photoelectric conversion layer are divided for each of the plurality of pixels by the trench.

(3)

The imaging device according to (1) or (2) further including a first intermediate layer provided between the first side surface and the first protective layer.

(4)

The imaging device according to (3), in which the first intermediate layer is an oxide film of the second compound semiconductor.

(5)

The imaging device according to (3) or (4), in which a bonding force between the first side surface and the first protective layer with the first intermediate layer interposed between the first side surface and the first protective layer is larger than a bonding force between the first side surface and the first protective layer in a case where the first protective layer is directly in contact with the first side surface without the first intermediate layer interposed between the first side surface and the first protective layer.

(6)

The imaging device according to any one of (1) or (5) further including a second intermediate layer provided between the second side surface and the second protective layer.

(7)

The imaging device according to (6), in which the second intermediate layer is an oxide film of the first compound semiconductor.

(8)

The imaging device according to (6) or (7), in which a bonding force between the second side surface and the second protective layer with the second intermediate layer interposed between the second side surface and the second protective layer is larger than a bonding force between the second side surface and the second protective layer in a case where the second protective layer is directly in contact with the second side surface without the second intermediate layer interposed between the second side surface and the second protective layer.

(9)

The imaging device according to any one of (1) to (8) further including a conductive layer that is embedded in the trench.

(10)

The imaging device according to any one of (1) to (9) further including

a semiconductor layer that is provided on an opposite side of the photoelectric conversion layer from the support substrate, the semiconductor layer including the first compound semiconductor; and

an insulating film that covers a surface of the semiconductor layer opposite to a surface of the semiconductor layer facing the photoelectric conversion layer,

in which the trench penetrates the semiconductor layer, and

a portion penetrating the semiconductor layer in the trench is filled with the insulating film.

(11)

The imaging device according to any one of (1) to (10), in which

the first compound semiconductor is InP,

the second compound semiconductor is InGaAs,

the first protective layer is a layer containing a metal oxide, and

the second protective layer is a layer containing an insulator.

(12)

The imaging device according to (11), in which the metal oxide is Al₂O₃, AlN, La₂O₃, or MgO.

(13)

The imaging device according to (11) or (12), in which the insulator is SiO₂ or SiN.

### REFERENCE SIGNS LIST

1 Imaging device
1a Pixel portion
10 Light receiving element
10, 10A, 10B, 10C, 10D, 10E, 10F, 10G Light receiving element (Compound semiconductor light receiving element)

### 20 Substrate

21 Semiconductor substrate
22 Photoelectric conversion layer
23 Semiconductor layer
24 First insulating film

### 25 Electrode

30 Multilayer wiring substrate
41 Second insulating film
43 Third insulating film
44 Color filter
44G Green filter
44R Red filter
45 On-chip lens
50 Pixel isolation portion
51 First protective layer
52 Second protective layer
53 Third protective layer
54 Fourth protective layer
55 Light shielding layer
56 Conductive layer
61 First intermediate layer
62 Second intermediate layer
230 Peripheral circuit unit
231 Row scanning unit
232 System control unit
233 Horizontal selection unit
234 Column scanning unit
235 Horizontal signal line

### H, H21, H23, H41 Trench

L1 First straight line portion
L2 Second straight line portion

1. An imaging device comprising:
a support substrate that includes a first compound semiconductor;
a photoelectric conversion layer that is provided on a first surface side of the support substrate and includes a second compound semiconductor having a composition different from a composition of the first compound semiconductor;
a first protective layer that is provided in a trench penetrating the support substrate and the photoelectric conversion layer and is provided on a first side surface of the photoelectric conversion layer; and
a second protective layer that is provided in the trench and is provided on a second side surface of the support substrate,
the first protective layer and the second protective layer having different compositions,
a first interface state generated between the first side surface and the first protective layer being smaller than an interface state generated between the first side surface and the second protective layer in a case where the second protective layer is in contact with the first side surface, and
a second interface state generated between the second side surface and the second protective layer being smaller than an interface state generated between the second side surface and the first protective layer in a case where the first protective layer is in contact with the second side surface.

2. The imaging device according to claim 1 further comprising
a plurality of pixels,
wherein the support substrate and the photoelectric conversion layer are divided for each of the plurality of pixels by the trench.

3. The imaging device according to claim 1 further comprising a first intermediate layer that is provided between the first side surface and the first protective layer.

4. The imaging device according to claim 3, wherein the first intermediate layer is an oxide film of the second compound semiconductor.

5. The imaging device according to claim 3, wherein a bonding force between the first side surface and the first protective layer with the first intermediate layer interposed between the first side surface and the first protective layer is larger than a bonding force between the first side surface and the first protective layer in a case where the first protective layer is directly in contact with the first side surface without the first intermediate layer interposed between the first side surface and the first protective layer.

6. The imaging device according to claim 1 further comprising a second intermediate layer that is provided between the second side surface and the second protective layer.

7. The imaging device according to claim 6, wherein the second intermediate layer is an oxide film of the first compound semiconductor.

8. The imaging device according to claim 6, wherein a bonding force between the second side surface and the second protective layer with the second intermediate layer interposed between the second side surface and the second protective layer is larger than a bonding force between the second side surface and the second protective layer in a case where the second protective layer is directly in contact with the second side surface without the second intermediate layer interposed between the second side surface and the second protective layer.

9. The imaging device according to claim 1 further comprising a conductive layer that is embedded in the trench.

10. The imaging device according to claim 1 further comprising:
a semiconductor layer that is provided on an opposite side of the photoelectric conversion layer from the support substrate, the semiconductor layer including the first compound semiconductor; and
an insulating film that covers a surface of the semiconductor layer opposite to a surface of the semiconductor layer facing the photoelectric conversion layer,
wherein the trench penetrates the semiconductor layer, and
a portion penetrating the semiconductor layer in the trench is filled with the insulating film.

11. The imaging device according to claim 1, wherein
the first compound semiconductor is InP,
the second compound semiconductor is InGaAs,
the first protective layer is a layer containing a metal oxide, and
the second protective layer is a layer including an insulator.

12. The imaging device according to claim 11, wherein the metal oxide is Al₂O₃, AlN, La₂O₃, or MgO.

13. The imaging device according to claim 11, wherein the insulator is SiO₂ or SiN.
